(19) United States
(12) Patent Application Publication
(10) Pub. No.: US 2009/0008067 A1
(43) Pub. Date: Jan. 8, 2009

(54) HEAT DISSIPATION DEVICE

(75) Inventor: ZHI-BIN KUAN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/778,551

(22) Filed: Jul. 16, 2007

(30) Foreign Application Priority Data
Jul. 4, 2007 (CN) 200710076386.4

(51) Int. Cl. H01L 23/467; H05K 7/20

(52) U.S. Cl. 165/121; 165/80.3; 361/697

(57) ABSTRACT

A heat dissipation device includes a heat sink (30) having a plurality of fins (34), and a cooling fan (10) surrounded by the fins. The cooling fan includes a frusto-conical hub (22) having a peripheral wall (222) and a concaved side wall (224) extending upwardly from the peripheral wall. A plurality of fan blades (24) are arranged on and around the hub. Each fan blade includes a radial-flow first portion (240) extending outwardly from the peripheral wall and a second portion (242) extending outwardly from the side wall; the second portions of the fan blades are inclined with respect to the first portions for guiding air to the first portions of fan blades when the fan is activated.

### BACKGROUND OF THE INVENTION

1. Field of the Invention

The present invention relates to a heat dissipation device, and more particularly relates to a cooling fan with an improved fan blade set for generating an airflow with a large volumetric flow rate.

2. Description of Related Art

With continuing development of the electronic technology, electronic packages such as the CPUs are generating more and more heat that is required to be dissipated immediately. Cooling fans are commonly used in combination with heat sinks for cooling the CPUs and other electronic products.

The cooling fan typically comprises a stator and a rotor being rotatable with respect to the stator. The rotor comprises a fan blade unit and a shaft extending downwardly from the fan blade unit. The stator comprises a bearing in which the shaft is ratatably received. In order to improve cooling and heat dissipation efficiency, the most direct and effective way is to increase the volumetric flow rate of the airflow generated by the cooling fan. Increasing the volumetric flow rate of the airflow can be achieved by different measures, for example, increasing the revolving speed of the fan blade unit or changing the design of the fan blade unit.

Increasing the revolving speed of the fan blade unit relatively increases the volumetric flow rate of the airflow; therefore, the cooling and heat dissipation effectiveness is relatively improved. However, increasing the revolving speed of the fan blade unit causes the bearing to wear quickly. The heat produced due to friction between the shaft and the bearing causes the bearing to be damaged quickly, resulting in short service life of the cooling fan. Furthermore, noise level generated by the rotating fan is also increased due to the increase of the fan speed. Therefore, it is not a good measure to increase the flow rate of the airflow by simply increasing the revolving speed of the fan blade unit. Further, increasing the revolving speed of the fan blade unit also results in waste of power and increase of temperature of the fan motor. Therefore, the better way to increase the flow rate of the airflow is to change the design of the fan blade unit.

### SUMMARY OF THE INVENTION

The present invention relates to a heat dissipation device including a heat sink and a cooling fan. The heat sink has a round base and a plurality of fins extending upwardly from an outer periphery of a top face of the base. The cooling fan is arranged on a central portion of the base with the fins surrounding therearound. The cooling fan includes a hub shaped like a frustum of a cone and having an annular-shaped peripheral wall at a bottom thereof and a concaved side wall extending upwardly from the peripheral wall to a flat top wall of the hub. A plurality of fan blades are arranged around the hub. Each fan blade includes a linear, radial-flow first portion extending outwardly from the peripheral wall and a curved second portion extending outwardly from the side wall; the second portions of the fan blades are inclined with respect to the first portions and the peripheral wall for guiding air therealong downwardly to the first portions of fan blades. The first portion of each fan blade is extended from a lower end of a corresponding second portion. The second portion of each fan blade has a linear top edge located adjacent to and above the top wall of the hub, and a concaved side edge located over the side wall of the hub and extending downwardly from an outer end of the top edge to an inner end of a corresponding first portion of the fan blade over the periphery wall.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an explored, isometric view of a heat dissipation device according to a preferred embodiment of the present invention;

FIG. 2 is an assembled view of the heat dissipation device of FIG. 1; and

FIG. 3 is a top plan view of a cooling fan of the heat dissipation device in FIG. 1.

### DETAILED DESCRIPTION OF THE INVENTION

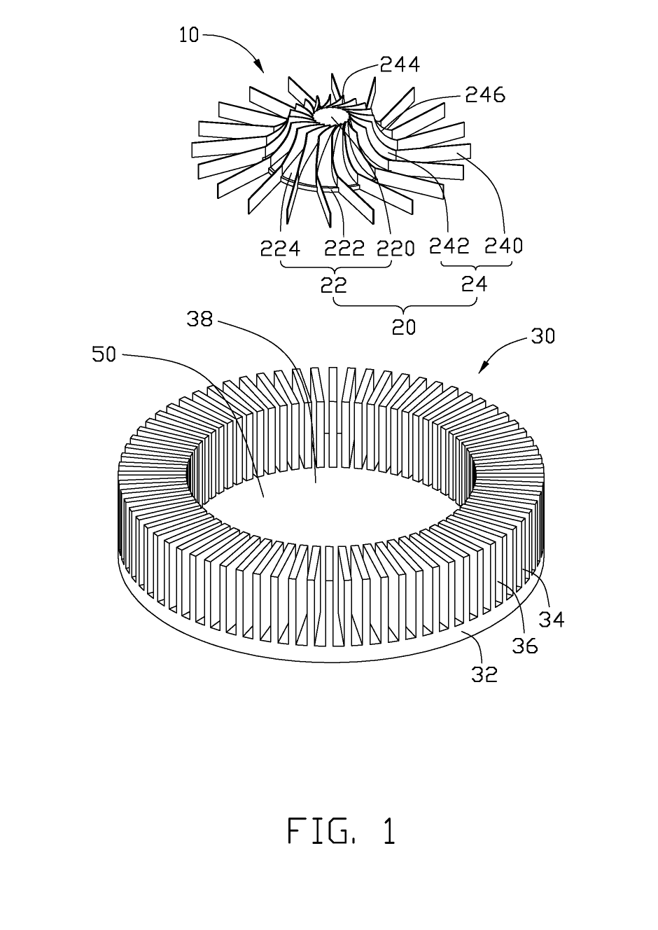

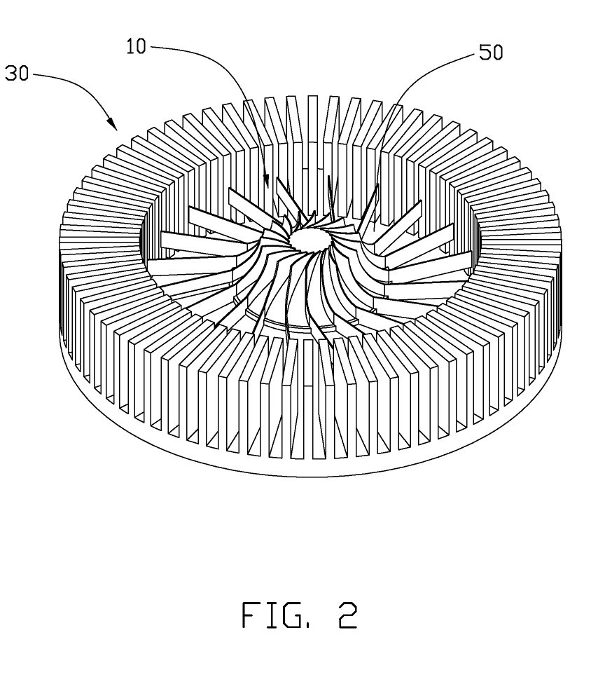

Referring to FIGS. 1 and 2, a heat dissipation device according to a preferred embodiment of the present invention is shown. The heat dissipation device includes a cooling fan 10 and a heat sink 30.

The heat sink 30 is made of highly thermally conductive material, such as copper, aluminum, or their alloys. The heat sink 30 as shown in this embodiment is an extruded aluminum heat sink, including a disk-shaped base 32 and a plurality of fins 34 extending upwardly from an outer periphery of a top face (not labeled) of the base 32. The base 32 has a bottom face (not labeled) for thermally connecting with a heat-generating electronic device, such as a central processing unit (CPU) of a computer. The fins 34 are plate-like fins, and are evenly arranged along a circumferential direction of the heat sink 30 and spaced from each other with a predetermined distance. A plurality of flow channels 36 are defined between any two neighboring fins 34. Each channel 36 has a width gradually increased along a radial direction of the heat sink 30 from a central portion 38 to the outer periphery of the base 32. The central portion 38 of the base 32 is surrounded by the fins 34 and thus defines a recessed space 50 in a center of the heat sink 30. In this embodiment, the fins 34 are integrally formed with the base 32. Apparently, the fins 34 are used for increasing the heat dissipation area of the heat sink 30. Alternatively, the fins 34 can be pin fins. The fins 34 and the base 32 can be formed separately, and then connected together by soldering.

The cooling fan 10 is received in the recessed space 50 of the heat sink 30 with the fins 34 surrounding therearound. The cooling fan 10 is a centrifugal blower, includes a stator (not shown) and a rotor (not labeled) being rotatable with respect to the stator. The rotor includes a fan blade set 20 and a shaft (not shown) extending downwardly from the fan blade set 20. The stator includes a bearing (not shown) ratatably receiving the shaft and thus supporting rotation of the shaft and the fan blade set 20. The fan blade set 20 includes a hub 22 having a configuration like a frustum of a cone, and a plurality of fan blades 24 extending from and arranged around the hub 22. The hub 22 includes a planar top wall 220, an annular-shaped peripheral wall 222 being arranged around a bottom end of the hub 22, and a side wall 224 interconnecting an outer periphery of the top wall 220 and the peripheral wall 222. The top wall 220 is circular and has a diameter being smaller than an outer diameter of the peripheral wall 222. The side wall 224 forms a concave-shaped outer surface, concaved along a top-to-bottom direction.

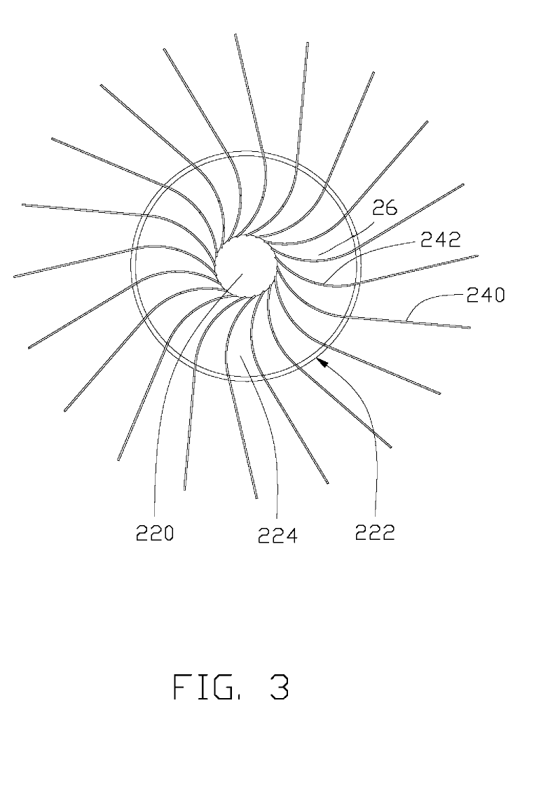

The fan blades 24 are integrally formed with the hub 22. Each of the fan blades 24 includes a linear first portion 240 and a curved second portion 242, as viewed from a top of the fan blade set 20 (FIG. 3). The first portions 240 are radial-flow blades that extend horizontally outwardly from the peripheral wall 222. Each first portion 240 of the fan blade 24 is planar-shaped. A height of the first portion 240 is larger than that of the peripheral wall 222, and a topmost edge of each first portion 240 of the fan blade 24 is higher than a top of the peripheral wall 222 in an axial direction of the fan blade set 20. The second portions 242 of the fan blades 24 are arranged on the side wall 224. The second portions 242 of the fan blades 24 are extended along the outer surface of the side wall 224 and thus are inclined with respect to the peripheral wall 222 and the first portions 240. Each second portion 242 extends from the outer periphery of the top wall 220 to a corresponding first portion 240 along the outer surface of the side wall 224. An air guide passage 26 is formed between two neighboring second portions 242. The second portion 242 of the fan blade 24 forms a linear-shaped top edge 244 and a concaved side edge 246. The top edge 244 of the second portion 242 of the fan blade 24 is parallel to and higher then the top wall 220. The side edge 246 of the second portion 242 extends downwardly from an outer end of the top edge 244 to an inner end of a corresponding first portion 240 over the peripheral wall 222. In a top plan view of the cooling fan 10 as shown in FIG. 3, the first portion 240 of each fan blade 24 is located at an outer side of the peripheral wall 222, and the second portion 242 of the fan blade 24 is located at an inner side of the peripheral wall 222, wherein the first portion 240 is extended from an outer end of a corresponding second portion 242.

During operation of the heat dissipation device, a center of the bottom face of the base 32 of the heat sink 30 is arranged on the heat-generating electronic device, such as the CPU (not shown), to absorb heat therefrom. The heat is then transferred from the base 32 to the fins 34 rapidly for dissipation. The cooling fan 10 is received in the space 50 of the heat sink 30 and draws ambient cooling air to the heat sink 30. The air current flows down into the channels 36 defined between the fins 34 for heat exchange with the fins 34. In the present invention, not only the first portions 240 continuously draw air current from above the fan blade set 20 to produce radial airflow, but also the second portions 242 of the fan blades 24 continuously draw air currents from above the second portions 242 to the first portions 240 of the fan blades 24 along the air guide passages 26, enabling the first portions 240 of the fan blades 24 to send out the air current to the fins 34 with a large volumetric flow rate to dissipate the heat of the heat-generating electronic device. By means of the action of the second portions 242 and the first portions 240 of the fan blades 24, an airflow with a large volumetric flow rate is produced to achieve a high cooling and heat dissipation effect without producing much noise and heat by the rotating fan. Each second portion 242 is curved from the top wall 220 to the peripheral wall 222, thereby reducing the resistance to the airflow and thus increasing the volumetric flow rate of the airflow.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat dissipation device, comprising:
a heat sink having a base and a plurality of fins extending upwardly from the base near an outer periphery of the base; and
a cooling fan being arranged on a central portion of the base with the fins surrounding therearound, the cooling fan comprising:
a frusto-conical hub having an annular-shaped peripheral wall at a bottom thereof, and a side wall extending upwardly from the peripheral wall, the side wall forming a concave-shaped outer surface; and
a plurality of fan blades being arranged on and around the hub, each fan blade comprising a radial-flow first portion extending radially outwardly from the peripheral wall and a second portion extending outwardly from the side wall, the second portions of the fan blades being inclined with respect to the peripheral wall and the first portions for guiding air to the first portions of the fan blades when the fan rotates;
wherein the first portion of each fan blade is located at an outer side of the peripheral wall and the second portion of the fan blade is located at an inner side of the peripheral wall, as viewed from a top of the hub.

2. The heat dissipation device of claim 1, wherein each of the second portions has a curve-shaped configuration and each of the first portions has a linear configuration, as viewed from a top of the hub.

3. The heat dissipation device of claim 1, wherein the first portions of the fan blades extend outwardly from outer ends of the second portions, respectively.

4. The heat dissipation device of claim 1, wherein each of the second portions of the fan blades has a linear-shaped top edge parallel to and higher than a top wall of the hub.

5. The heat dissipation device of claim 1, wherein each first portion of the fan blades has a height larger than that of the peripheral wall, and a topmost edge of the each first portion of the fan blades is higher than a top of the peripheral wall.

6. The heat dissipation device of claim 4, wherein each second portion of the fan blades is located between the peripheral wall and the top wall of the hub.

7. The heat dissipation device of claim 1, further comprising a circular-shaped top wall connected to a top of the side wall, wherein the top wall has a diameter smaller than an outer diameter of the peripheral wall.

8. The heat dissipation device of claim 1, wherein the fan blades are integrally formed with the hub, and the second portions of the fan blades extend from the first portions to a top of the side wall.

9. The heat dissipation device of claim 1, wherein the heat sink is an extruded heat sink, the fins being plate fins and being integrally formed with the base of the heat sink.

10. A cooling fan comprising a fan blade set, the fan blade set comprising:
a frusto-conical hub and a plurality of fan blades arranged on and around the hub, each of the fan blades comprising:
a first portion being planar-shaped and extending radially outwardly from a bottom of the hub, and
a second portion for guiding air over the hub to the first portion, the second portions being arc-shaped as viewed from a top of the hub and connecting a top of the hub and the first portions of the fan blades, respectively;
wherein the first portion of each fan blade is located at an outer side of an outmost edge of the hub and the second portion of the fan blade is located at an inner side of the outmost edge of the hub, as viewed from a top of the hub.

11. The cooling fan of claim 10, wherein the hub has a side wall and a peripheral wall depending from the side wall, the side wall forming a concave-shaped outer surface with the second portions of the blades formed thereon, the first portions of the fan blades extending radially outwardly from the peripheral wall.

12. The cooling fan of claim 11, wherein a circular-shaped top wall is connected to a top of the side wall, the top wall has a diameter being smaller than an outer diameter of the peripheral wall.

13. The cooling fan of claim 12, wherein the second portions of the fan blades have top edges which are higher than the top wall.

14. The cooling fan of in claim 13, wherein each of the top edges of the second portions is linear-shaped and parallel to the top wall.
